(19) United States
(12) Patent Application Publication
(10) Pub. No.: US 2024/0170493 A1
(43) Pub. Date: May 23, 2024

(54) DISPLAY PANEL AND METHOD OF FABRICATING SAME

(71) Applicant: GUANGZHOU CHINA STAR OPTOELECTRONICS SEMICONDUCTOR DISPLAY TECHNOLOGY CO., LTD., Guangzhou, Guangdong (CN)

(72) Inventor: Yanhong Meng

(73) Assignee: GUANGZHOU CHINA STAR OPTOELECTRONICS SEMICONDUCTOR DISPLAY TECHNOLOGY CO., LTD., Guangzhou, Guangdong (CN)

(21) Appl. No.: 17/758,027

(22) PCT Filed: May 31, 2022
(86) PCT No.: PCT/CN2022/096360

§ 371 Date: Jun. 26, 2022

(30) Foreign Application Priority Data
May 19, 2022 (CN) 202210553909.4

(51) Int. Cl. H01L 27/12

(52) U.S. Cl. CPC H01L 27/1222; H01L 27/124; H01L 27/1251; H01L 27/127; H01L 27/1288

(57) ABSTRACT

The present application relates to a display panel and a method of fabricating a display panel. The display panel includes a plurality of pixel units arranged in an array, at least one of the pixel units is provided with a first transistor and a second transistor. The first transistor includes a first gate electrode, a first source electrode and a first drain electrode, and the second transistor includes a second gate electrode, a second source electrode and a second drain electrode. The first source electrode, the first drain electrode and the second gate are in the same layer.

### FIELD OF INVENTION

The present application relates to fields of display technology, and particularly to a display panel and a method of fabricating same.

### BACKGROUND

In the related art, fabrication processes of a light sensing circuit are complex, resulting in a long production cycle and high costs. For example, in the related art, when fabricating a photosensitive circuit, a photosensitive transistor is first fabricated, and then a driver transistor is fabricated. Fabricating processes of the photosensitive transistor and the driver transistor are carried out independently, and the required photomask processes are relatively complex.

### SUMMARY OF DISCLOSURE

The present application is mainly aimed at the technical problems of the complex photomask process of the photosensitive circuit.

Accordingly, a display panel and a method of fabricating a display panel are provided, and a first source electrode, a first drain electrode and a second gate electrode can be fabricated in one process, thereby reducing the number of times of the photomask to be used, improving the fabrication efficiency of the display panel, and further reducing the production cost, which is simple and convenient.

According to an aspect of the present application, a display panel is provided, wherein the display panel comprises a plurality of pixel units arranged in an array, at least one of the pixel units is provided with a first transistor and a second transistor, the first transistor comprises a first gate electrode, a first a source electrode and a first drain electrode, and the second transistor comprises a second gate electrode, a second source electrode, and a second drain electrode. The first source electrode, the first drain electrode and the second gate electrode are in the same layer.

Furthermore, the display panel further comprises a substrate, wherein the first gate electrode is arranged on the substrate; a first gate insulating layer arranged on the first gate electrode; a first active layer arranged on the first gate insulating layer, at least partially overlapping the first gate electrode; a first source electrode and a first drain electrode arranged on the first active layer; a second gate insulating layer arranged on the first source electrode and the first drain electrode; and a second active layer arranged on the second gate insulating layer, wherein the second active layer and the second gate electrode are at least partially overlapped.

Furthermore, one end of the second gate electrode is attached to the first gate insulating layer, and the other end of the second gate electrode is level with one end of the second source layer.

Furthermore, the display panel further comprises: a second source electrode and a second drain electrode, wherein the second source electrode and the second drain electrode are arranged on the second active layer at intervals; a planarization layer arranged on the second source electrode and the second drain electrode, wherein the planarization layer is provided with a via hole exposing at least one of the second source electrode and the second drain electrode; and the first metal layer is disposed on the planarization layer, and the first metal layer is extended in the via hole and connected to at least one of the second source electrode and the second drain electrode.

Furthermore, the first source electrode, the first drain electrode, and the second gate electrode are arranged at intervals, and the display panel comprises a connection line, the connection line and the second gate electrode are arranged in the same layer to electrically connect the second gate electrode with one of the first source electrode or the first drain electrode.

Furthermore, one end of the connection line is attached to the first active layer, and the other end of the connection line is in contact with one end of the second gate electrode.

Furthermore, the first active layer is made of an amorphous silicon material, and the second active layer is made of an oxide semiconductor material.

Furthermore, the first transistor is a photosensitive transistor used for sensing external light and generating a photosensitive signal when the light is sensed.

Furthermore, the second transistor is a driver transistor used for transmitting the photosensitive signal to a gate of the drive transistor through a drain or a source of the driver transistor of the photosensitive transistor and the connection when the photosensitive transistor senses the light.

Furthermore, the first gate electrode, the first source electrode, the first drain electrode, the second gate electrode, the second source electrode, and the second drain electrode are all made of a metal layer.

Furthermore, the first transistor is N-type or a P-type, and the second transistor is N-type or a P-type.

According to another aspect of the present application, a method of fabricating a display panel is provided, and the method of fabricating the display panel is used for the display panel, comprising: providing a substrate; depositing a first gate electrode of a first transistor on the substrate; depositing the first gate insulating layer on the first gate electrode; depositing a first active layer of the first transistor on the first gate insulating layer; depositing a second metal layer is deposited on the first active layer and the first gate insulating layer and patterning the second metal layer to form a first source electrode, a first drain electrode and a second gate electrode at intervals.

Furthermore, the first active layer is formed based on a first photomask, and the first source electrode, the first drain electrode and the second gate are formed based on a second photomask.

Furthermore, the method of fabricating the display panel further comprises forming a second gate insulating layer on the first source electrode, the first drain electrode, and the second gate electrode; forming a second active layer on the second gate insulating layer; and depositing a third metal layer on the second active layer and patterning the third metal layer to form the second drain electrode and the second source electrodes at intervals. Furthermore, the second drain electrode and the second source electrode are formed based on a third photomask, and the third photomask is a halftone mask.

Furthermore, patterning the second metal layer further comprises simultaneously forming a connecting line, and the connection line is electrically connected to the second gate electrode and the source electrode or the first drain electrode.

Furthermore, patterning the second metal layer further comprises depositing a planarization layer on the second source electrode and the second drain electrode; and etching and forming a via hole at a position of the planarization layer corresponding to at least one of the second source electrode and the second drain electrode.

Furthermore, the planarization layer and the via hole are formed based on a fourth photomask.

Furthermore, the display panel according to claim 12, wherein patterning the second metal layer further comprise filling the etched via hole with a metal layer.

Furthermore, patterning of the second metal layer further comprises filling the metal layer in the etched via hole based on a fifth photomask.

Accordingly, beneficial effects of the embodiments of the present invention are:

By arranging the first source electrode and the first drain electrode of the first transistor in at least one pixel unit and the second gate electrode of the corresponding second transistor in the pixel unit to be the same layer, according to various aspects of the present application, the first source electrode, the first drain electrode and the second gate electrode are fabricated in one process, which reduces the number of times the photomask to be used, improves the fabrication efficiency of the display panel, further reduces the production cost, which is simple and convenient.

### BRIEF DESCRIPTION OF DRAWINGS

In order to more clearly illustrate technical solutions in embodiments of the present disclosure, a brief description of accompanying drawings used in a description of the embodiments will be given below. Obviously, the accompanying drawings in the following description are merely some embodiments of the present disclosure. For those skilled in the art, other drawings may be obtained from these accompanying drawings without creative labor.

FIG. 1 is a schematic diagram showing a display panel according to an embodiment of the present application.

FIGS. 2-6 are schematic diagrams showing a method of fabricating a display panel according to an embodiment of the present application.

### DETAILED DESCRIPTION

Technical solutions in the embodiments of the present application will be clearly and completely described below with reference to the accompanying drawings in the embodiments of the present application. Obviously, the described embodiments are only a part of the embodiments of the present application but not all of the embodiments. Based on the embodiments in this application, all other embodiments obtained by those skilled in the art without creative efforts shall fall within the protection scope of this application.

In the description of this application, it should be understood that the terms “center”, “longitudinal”, “lateral”, “length”, “width”, “thickness”, “upper”, “lower”, “front”, “rear, left, right, vertical, horizontal, top, bottom, inside, outside, clockwise, counterclockwise, etc., or The positional relationship is based on the orientation or positional relationship shown in the drawings, which is only for the convenience of describing the present application and simplifying the description, rather than indicating or implying that the device or element referred to must have a specific orientation, be constructed and operated in a specific orientation, Therefore, it should not be construed as a limitation on this application. In addition, the terms “first” and “second” are only used for descriptive purposes and should not be construed as indicating or implying relative importance or implying the number of indicated technical features. Thus, features defined as “first”, “second” may expressly or implicitly include one or more of said features. In the description of the present application, “plurality” means two or more, unless otherwise expressly and specifically defined.

In the description of this application, it should be noted that, unless otherwise expressly specified and limited, the terms “installed”, “connected” and “connected” should be understood in a broad sense, for example, it may be a fixed connection or a detachable connection or integral connection. It can be a mechanical connection, an electrical connection or can communicate with each other. It can be a direct connection or an indirect connection through an intermediate medium, it can be the internal communication of two elements or the interaction of two elements relation. For those of ordinary skill in the art, the specific meanings of the above terms in this application can be understood according to specific situations.

The following disclosure provides many different embodiments or examples for implementing different structures of the present application. To simplify the disclosure of the present application, the components and arrangements of specific examples are described below. Of course, they are only examples and are not intended to limit the application. Furthermore, this application may repeat reference numerals and/or reference letters in different instances for the purpose of simplicity and clarity and does not in itself indicate a relationship between the various embodiments and/or arrangements discussed. In addition, this application provides examples of various specific processes and materials, but one of ordinary skill in the art will recognize the application of other processes and/or the use of other materials. In some instances, methods, means, components and circuits well known to those skilled in the art have not been described in detail so as not to obscure the subject matter of the present application.

The present application mainly provides a display panel, and the display panel comprises a plurality of pixel units arranged in an array, at least one of the pixel units is provided with a first transistor and a second transistor, and the first transistor comprises a first gate electrode, a first source electrode and a first drain electrode, the second transistor comprises a second gate electrode, a second source electrode and a second drain electrode. The first source electrode, the first drain electrode and the second gate electrode are in the same layer.

By arranging the first source electrode and the first drain electrode of the first transistor in at least one pixel unit and the second gate electrode of the corresponding second transistor in the pixel unit to be the same layer, according to various aspects of the present application, the first source electrode, the first drain electrode and the second gate electrode are fabricated in one process, which reduces the number of times the photomask to be used, improves the fabrication efficiency of the display panel, further reduces the production cost, which is simple and convenient.

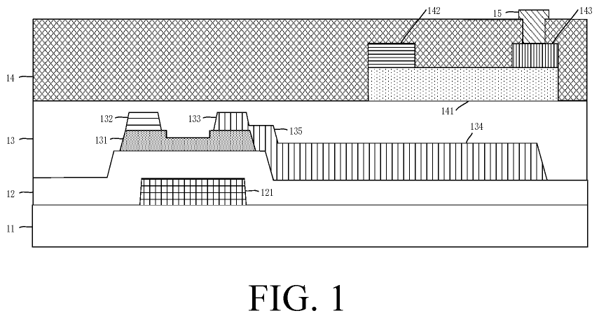

FIG. 1 is a schematic diagram showing a display panel according to an embodiment of the present application.

As shown in FIG. 1, the display panel of the present application may comprise a substrate 11, a first gate insulating layer 12, a second gate insulating layer 13, and a planarization layer 14 that are stacked in sequence. The substrate 11, the first gate insulating layer 12, the second gate insulating layer 13, and the planarization layer 14 may be stacked in sequence along a direction perpendicular to the substrate. A first transistor and a second transistor of the same pixel unit are arranged on the same side of the substrate.

It should be noted that, what is shown in FIG. 1 may be a cross-sectional view of a pixel unit. In the present application, the first transistor and the second transistor may be provided in some pixel units, or the first transistor and the second transistor may be provided in each of the pixel units. For the same pixel unit, the number of the first transistor in the pixel unit may be one or more, and the number of the second transistor in the pixel unit may also be one or more. It can be understood that the present application does not limit the number of pixel units, the first transistors, and the second transistors.

In a pixel unit, the first transistor may be a photosensitive transistor, which is used for sensing external light and generating carriers in a channel of the photosensitive transistor when receiving light, thereby generating photosensitive signals. The photosensitive signals may be current signals or voltage signals. The second transistor may be a driver transistor used for transmitting the photosensitive signals to a gate of the driver transistor through a drain or source of the photosensitive transistor and connecting lines when the photosensitive transistor senses light so as to turn on the driver transistor to drive a corresponding pixel electrode. Both the first transistor and the second transistor may be a bottom-gate structure. It can be understood that the types of the first transistor and the second transistor are exemplary, and the present application does not limit the type of the first transistor and the second transistor.

Furthermore, a first gate electrode, a first source electrode, a first drain electrode, a second gate electrode, a second source electrode, and a second drain electrode may be all made of metal layers. A material of the metal layers may be copper or other materials such as silver, which is not limited in this application.

For example, in the present application, the first transistor may be an electronic device such as a MOSFET. Both the first transistor and the second transistor may be N-type or P-type. Alternatively, the first transistor is N-type, and the second transistor is P-type. Alternatively, the first transistor is P-type, and the second transistor is N-type.

Furthermore, the display panel further comprises a substrate, a first gate insulating layer, a first active layer, a first source electrode, a first drain electrode and a second active layer. The first gate electrode is arranged on the substrate, the first gate insulating layer is arranged on the first gate, and the first active layer is arranged on the first gate insulating layer to at least partially overlap the first gate electrode. The first source electrode and the first drain electrode are arranged on the active layer, the second gate insulating layer is arranged on the first source electrode and the first drain electrode. The second active layer is arranged on the second gate insulating layer, and the second active layer and the second gate electrode are at least partially overlapped.

Furthermore, the substrate may be an array substrate, and the array substrate may be a glass substrate. The glass substrate can be transparent, semi-transparent or opaque to block moisture and oxygen and provide a flat upper surface.

Furthermore, the first gate electrode is arranged on the substrate, and the first gate insulating layer is arranged on the first gate electrode. The first gate insulating layer can be made of a single-layer of SiNx material or a single-layer of SiOx material, or a double-layered film.

Furthermore, the first active layer is arranged on the first gate insulating layer to at least partially overlap the first gate electrode. For example, in FIG. 1, the first gate electrode 121 is arranged on the substrate 11, and the first gate electrode 121 is arranged directly under the first active layer 131. That is, the first gate electrode 121 and an orthographic projection of the first active layer 131 on the substrate 11 are correspondingly arranged. The first gate insulating layer 12 may cover the first gate electrode 121. The first active layer is made of amorphous silicon material. In one example, the first transistor may be a thin film transistor (TFT). The amorphous silicon material is also called α-Si material, and the amorphous silicon material can be deposited on a substrate with a large area, thereby further reducing the cost.

Furthermore, the first source electrode and the first drain electrode are arranged on the active layer. For example, in FIG. 1, taking the first transistor as an N-type transistor, the first source electrode 132 and the first drain electrode 133 may be arranged on the first active layer 131.

Furthermore, the second gate insulating layer is arranged on the first source electrode and the first drain electrode. The second gate insulating layer can be made of a material such as SiNx and SiOx to form a thin film, thereby forming a flat bearing surface.

Furthermore, the display panel further comprises a second active layer, the second active layer is arranged on the second gate insulating layer, and the second active layer and the second gate are at least partially overlapped. Specifically, one end of the second gate electrode is attached to the first gate insulating layer, and the other end of the second gate electrode is level with one end of the second active layer. For example, in FIG. 1, the second active layer 141 may be arranged on the second gate insulating layer 13, and the second active layer 141 and the second gate electrode 134 may be at least partially overlapped. The second gate electrode 134 may extend to just below the second active layer 141 in a horizontal direction, and a right boundary of the second gate electrode 134 may coincide with a right boundary of the second active layer 141.

The second active layer is made of oxide semiconductor materials. The oxide semiconductor materials may be an indium gallium zinc oxide (IGZO) material. It can be understood that other materials may also be used for the second active layer, which is not limited in this application.

Furthermore, the display panel further comprises a second source electrode, a second drain electrode, a planarization layer, and a first metal layer. The second source electrode and the second drain electrode are arranged on the second active layer at intervals. The planarization layer is arranged on the second source electrode and the second drain electrode. The planarization layer is provided with a via hole for exposing at least one of the second source electrode and the second drain electrode. The first metal layer is arranged on the planarization layer, and the first metal layer is arranged on the planarization layer. The first metal layer is extended in the via hole and connected to at least one of the second source electrode and the second drain electrode.

For example, in FIG. 1, the second source electrode 142 and the second drain electrode 143 are arranged on the second active layer 141 at intervals. The planarization layer 14 is arranged on the second source electrode 142 and the second drain electrode 143, and the planarization layer 14 is provided with a via hole, which can be used to expose the second drain electrode 143, so that the second drain electrode 143 is electrically connected to a corresponding first metal layer. The first metal layer 15 is arranged on the planarization layer 14, and the first metal layer 15 may be extended in the via hole to electrically connect the second drain electrode 143.

The first metal layer may be a transparent indium tin oxide (ITO) electrode. The first metal layer may be connected to a data line to deliver data signals for the second transistor.

Furthermore, the first source electrode, the first drain electrode and the second gate electrode are arranged at intervals. The display panel comprises a connection line, the connection line and the second gate electrode are arranged in the same layer, and the second gate and one of the first source or the first drain are electrically connected. The connection line is located between the first source electrode or the first drain electrode and the second gate electrode. Photosensitive signals are transmitted from the source electrode or the drain electrode of the first transistor to the gate of the second transistor. The second gate insulating layer may simultaneously cover the first source electrode, the first drain electrode, the connection line and the second gate electrode.

One end of the connection line is disposed in contact with the first active layer, and the other end of the connection line is in contact with one end of the second gate electrode. Referring to FIG. 1, taking the N-type first transistor as an example, the first drain electrode 133 can be electrically connected to the second gate 134 through a connection line 135. That is, the first drain electrode of the first transistor may be shared with the second gate electrode of the second transistor, or the first drain electrode of the first transistor may be multiplexed as the second gate electrode of the second transistor. For example, the connection line may cover the first active layer. That is, the connection line may be disposed close to the first active layer. It can be understood that the present application does not limit how the first drain electrode and the second gate electrode are electrically connected.

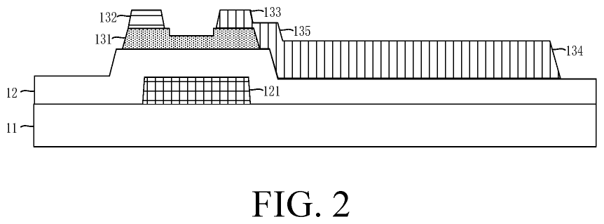

FIGS. 2-6 are schematic diagrams showing a method of fabricating a display panel according to an embodiment of the present application.

As shown in FIGS. 2-6, the present application further provides a method of fabricating a display panel, and the method of fabricating the display panel is applied to the above display panel. The method of fabricating the display panel comprises following steps.

Step S11: fabricating a substrate.

Step S12: depositing the first gate electrode of a first transistor on the substrate.

Step S13: depositing a first gate insulating layer on the first gate electrode.

Step S14: depositing the first active layer of the first transistor on the first gate insulating layer.

Step S15: depositing a second metal layer on the first active layer and the first gate insulating layer and patterning the second metal layer to form the first source electrode, the first drain electrode, and the second gate electrode arranged at intervals.

The steps S11-S15 can be fabricated by using a 2W2D process. The 2W2D process comprises a first step of a first wet etching, a second step of a first dry etching, a third step of a second wet etching, and a fourth step of second dry etching. When fabricating the first active layer, a first photomask (i.e., a mask layer or a mask) is needed, and the first photomask is used to define a pattern of the first active layer. When fabricating the first source electrode or a first drain electrode of the first transistor, a second photomask is needed to be used, and patterns of the first source electrode or the first drain electrode of the first transistor are defined by the second mask.

Referring to FIG. 2, the substrate 11 may be fabricated first. Next, the first gate electrode 121 of a first transistor is deposited on the substrate, then the first gate insulating layer 12 is deposited on the first gate electrode, then first active layer 131 of the first transistor is deposited on the first gate insulating layer, and a second metal layer is finally deposited on the first active layer and the first gate insulating layer, and the second metal layer is patterned to form a first source electrode 132, a first drain electrode 133, and a second gate electrode 134 that are arranged at intervals.

The step of fabricating of the second metal layer further comprises following steps.

Step S151: simultaneously forming a connection line, and the connection line electrically connects the second gate electrode and the first source electrode or the first drain electrode. That is, when the first source electrode or the first drain electrode and the second gate electrode are formed, the second metal layer is also patterned to form the connection line 135.

Furthermore, the method of fabricating the display panel may further comprises following steps.

Step S21: forming a second gate insulating layer on the first source electrode, the first drain electrode and the second gate electrode.

Step S22: forming a second active layer on the second gate insulating layer.

Step S23: depositing a third metal layer on the second active layer, and patterning the third metal layer to form second drain electrodes and second source electrodes that are spaced apart.

The present application may use a half-tone mask (i.e., HTM) to etch the second active layer and the third metal layer for obtaining the second active layer, the second source electrode and the second drain electrode of the second transistor. The halftone mask is the third photomask.

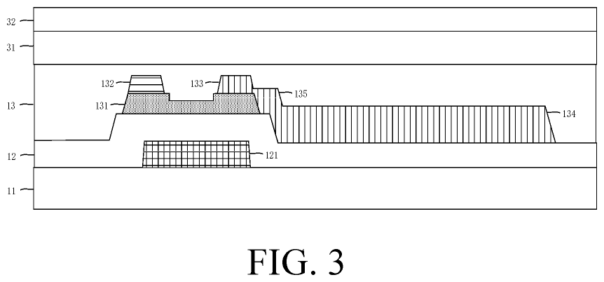

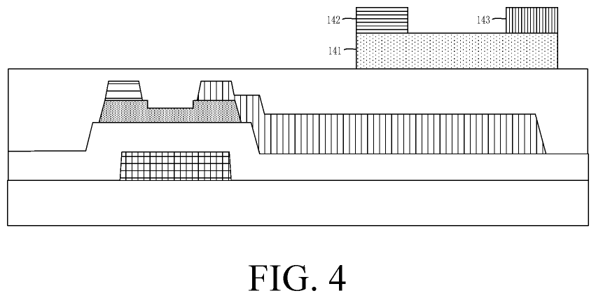

Referring to FIG. 3 and FIG. 4, the second gate insulating layer 13 may be deposited on the first gate electrode and the first drain electrode, and then an IGZO layer 31 may be deposited on the second gate insulating layer. A third metal layer 32 is deposited on the IGZO layer, the IGZO layer 31 is etched to obtain the second active layer 141 of the second transistor, and then the third metal layer 32 is etched to obtain the second source electrode deposited on the second active layer 142 and the second drain electrode 143.

Furthermore, the method of fabricating the display panel may further comprises following steps.

Step S31: depositing a planarization layer on the second source electrode and the second drain electrode.

Step S32: etching and forming a via hole at a position of the planarization layer corresponding to at least one of the second source electrode and the second drain electrode.

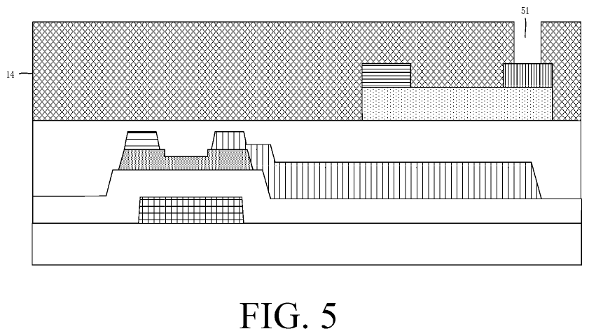

Referring to FIG. 5, a planarization layer 14 may be deposited on the second source electrode and the second drain electrode, and then the via hole 51 is etched and formed at place of the planarization layer corresponds to at least one of the second source electrode and the second drain electrode. The step S31 and the step S32 need to be performed by a fourth photomask.

Furthermore, the method of fabricating the display panel may further comprises following steps.

Step S41: filling the etched via hole with a metal layer.

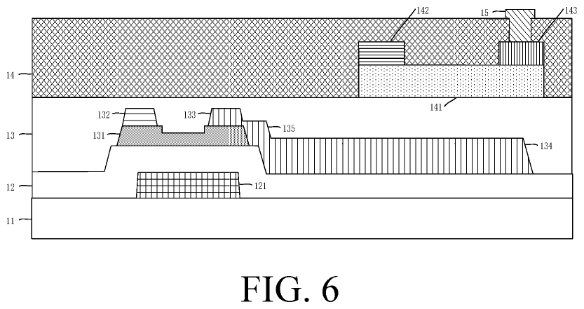

Referring to FIG. 6, the metal layer 15 may be filled in the etched via hole 51. In the step S41, a fifth photomask is needed to be used to define the pattern of the ITO electrode.

It should be noted that FIGS. 2-6 are exemplary embodiments. Based on the inventive concept of the present application, corresponding adjustments can be made in terms of process steps in practical applications. For a more detailed description of the fabrication method of the display panel, reference may be made to the above-mentioned specific description of the display panel, which will not be repeated.

Therefore, since the first source electrode and the first drain electrode of the first transistor in at least one pixel unit and the second gate electrode of the second transistor in the corresponding pixel unit are set to be the same layer, the actual production processes of the present application can fabricate the first source electrode, the first drain electrode and the second gate electrode in one process, thereby reducing the number of the photomask to five, improving the fabrication efficiency of the display panel, and further reducing the production costs.

To sum up, in the embodiments of the present application, the first source electrode and the first drain electrode of the first transistor in at least one pixel unit and the second gate electrode of the corresponding second transistor in the pixel unit are arranged in the same layer. The first source electrode, the first drain electrode and the second gate electrode can be fabricated in one process, thereby reducing the number of times of the photomask used in the fabrication, improving the fabrication efficiency of the display panel, and further reducing the production costs. The method can be used in many fields such as LCD, OLED, u-LED and mini-LED.

In the above-mentioned embodiments, the description of each embodiment has its own emphasis. For parts that are not described in detail in a certain embodiment, reference may be made to the relevant descriptions of other embodiments.

The display panel and the method of fabricating the display panel provided by the embodiments of the present application have been introduced in detail above. Specific examples are used in this article to illustrate the principles and implementations of the present application. The description of the above embodiments is only used to help understand the present application The method of application and its core idea; meanwhile, for those skilled in the art, according to the idea of this application, there will be changes in the specific implementation and the scope of application. In summary, the content of this specification should not be understood as restrictions on this application.

What is claimed is:

1. A display panel, wherein the display panel comprises a plurality of pixel units arranged in an array, at least one of the plurality of pixel units is provided with a first transistor and a second transistor, the first transistor comprises a first gate electrode, a first a source electrode and a first drain electrode, and the second transistor comprises a second gate electrode, a second source electrode, and a second drain electrode;
wherein the first source electrode, the first drain electrode and the second gate electrode are in the same layer.

2. The display panel according to claim 1, wherein the display panel further comprises:
a substrate, wherein the first gate electrode is arranged on the substrate;
a first gate insulating layer arranged on the first gate electrode;
a first active layer arranged on the first gate insulating layer, at least partially overlapping the first gate electrode;
a first source electrode and a first drain electrode arranged on the first active layer;
a second gate insulating layer arranged on the first source electrode and the first drain electrode; and
a second active layer arranged on the second gate insulating layer, wherein the second active layer and the second gate electrode are at least partially overlapped.

3. The display panel according to claim 2, wherein one end of the second gate electrode is attached to the first gate insulating layer, and the other end of the second gate electrode is level with one end of the second source layer.

4. The display panel according to claim 3, wherein the display panel further comprises:
a second source electrode and a second drain electrode, wherein the second source electrode and the second drain electrode are arranged on the second active layer at intervals;
a planarization layer arranged on the second source electrode and the second drain electrode, wherein the planarization layer is provided with a via hole exposing at least one of the second source electrode and the second drain electrode; and
the first metal layer is arranged on the planarization layer, wherein the first metal layer is extended in the via hole and connected to at least one of the second source electrode and the second drain electrode.

5. The display panel according to claim 4, wherein the first source electrode, the first drain electrode, and the second gate electrode are arranged at intervals, and the display panel comprises a connection line, the connection line and the second gate electrode are arranged in the same layer to electrically connect the second gate electrode with one of the first source electrode or the first drain electrode.

6. The display panel according to claim 5, wherein one end of the connection line is attached to the first active layer, and the other end of the connection line is in contact with one end of the second gate electrode.

7. The display panel according to claim 2, wherein the first active layer is made of an amorphous silicon material, and the second active layer is made of an oxide semiconductor material.

8. The display panel according to claim 5, wherein the first transistor is a photosensitive transistor used for sensing external light and generating a photosensitive signal when the external light is sensed.

9. The display panel according to claim 8, wherein the second transistor is a driver transistor used for transmitting the photosensitive signal to a gate of the drive transistor through a drain or a source of the driver transistor of the photosensitive transistor and the connection line when the photosensitive transistor senses the external light.

10. The display panel according to claim 1, wherein the first gate electrode, the first source electrode, the first drain electrode, the second gate electrode, the second source electrode, and the second drain electrode are all made of a metal layer.

11. The display panel according to claim 1, wherein the first transistor is N-type or a P-type, and the second transistor is N-type or a P-type.

12. A method of fabricating a display panel, wherein the method of fabricating the display panel comprises:
providing a substrate;
depositing a first gate electrode of a first transistor on the substrate;
depositing the first gate insulating layer on the first gate electrode;
depositing a first active layer of the first transistor on the first gate insulating layer;
depositing a second metal layer is deposited on the first active layer and the first gate insulating layer and patterning the second metal layer to form a first source electrode, a first drain electrode and a second gate electrode that are arranged at intervals.

13. The method of fabricating the display panel according to claim 12, wherein the first active layer is formed based on a first photomask, and the first source electrode, the first drain electrode and the second gate are formed based on a second photomask.

14. The method of fabricating the display panel according to claim 12, wherein the method of fabricating the display panel further comprises:
forming a second gate insulating layer on the first source electrode, the first drain electrode, and the second gate electrode;
forming a second active layer on the second gate insulating layer; and
depositing a third metal layer on the second active layer and patterning the third metal layer to form the second drain electrode and the second source electrodes at intervals.

15. The method of fabricating the display panel according to claim 14, wherein the second drain electrode and the second source electrode are formed based on a third photomask, and the third photomask is a halftone mask.

16. The method of fabricating the display panel according to claim 12, wherein patterning the second metal layer further comprises simultaneously forming a connecting line, and the connection line is electrically connected to the second gate electrode and the source electrode or the first drain electrode.

17. The method of fabricating the display panel according to claim 12, wherein patterning the second metal layer further comprises:
depositing a planarization layer on the second source electrode and the second drain electrode; and
etching and forming a via hole at a position of the planarization layer corresponding to at least one of the second source electrode and the second drain electrode.

18. The method of fabricating the display panel according to claim 17, wherein the planarization layer and the via hole are formed based on a fourth photomask.

19. The method of fabricating the display panel according to claim 12, wherein patterning the second metal layer further comprise filling the etched via hole with a metal layer.

20. The method of fabricating the display panel according to claim 19, wherein patterning of the second metal layer further comprises filling the metal layer in the etched via hole based on a fifth photomask.
